(19) United States
(12) Patent Application Publication
(10) Pub. No.: US 2026/0092356 A1
(43) Pub. Date: Apr. 2, 2026

(54) COATING FOR DONOR SUBSTRATE IN LASER INDUCED FORWARD TRANSFER REPAIR OF SUBSTRATE PROCESS

(71) Applicant: Orbotech Ltd., Yavne (IL)

(72) Inventors: Efraim DVASH, Hulda (IL); Asaf LEVY, Beer Sheva (IL); Ofir YEARI, Yavne (IL); Haim CHAYET, Yavne (IL)

(21) Appl. No.: 19/047,177

(22) Filed: Feb. 6, 2025

Related U.S. Application Data
(60) Provisional application No. 63/701,904, filed on Oct. 1, 2024.

(51) Int. Cl. C23C 14/28; C23C 14/16

(52) U.S. Cl. CPC C23C 14/28; C23C 14/16

(57) ABSTRACT

A donor composition used in a substrate repair process includes a donor substrate. The donor composition also includes a first layer of a first metallic material disposed adjacent to the donor substrate. The donor composition further includes a second layer of a second metallic material disposed adjacent to the first layer. The donor composition yet further includes a third layer of a third metallic material disposed adjacent to the second layer. The donor composition also includes a plurality of deposition layers of one or more metallic materials disposed adjacent to the third layer.

### CROSS-REFERENCE TO RELATED APPLICATION

This application claims the benefit of priority to U.S. Provisional Patent Application Serial No. 63/701,904, filed October 1, 2024, the disclosure of which is incorporated by reference herein in its entirety.

### FIELD OF THE INVENTION

The embodiments described herein relate to methods and systems for repairing a substrate using Laser Induced Forward Transfer (LIFT) and, more particularly, to a coating for a donor substrate used in a LIFT process.

### BACKGROUND

Laser Induced Forward Transfer (LIFT) technology offers an attractive cost/performance ratio for manufacturing and repair of printed circuit boards (PCBs), integrated circuits (IC) substrates, flat panel displays (FPDs) and other electronic device components. In the LIFT process, the laser photons are used as the triggering driving force to eject a small volume of material from a source film (known as “donor”) toward a substrate (known as “acceptor” or “receiver”). In a repair process, this is done to close an “open” defect with an additive process, whereas the removal in a “short” defect is done by laser ablation process.

U.S. Pat. No. 4,970,196, whose disclosure is incorporated herein by reference, describes a method and apparatus for thin film deposition of materials with a high power pulsed laser. Laser direct writing of materials is accomplished by positioning a receiving substrate opposite a high power pulsed laser source and disposing therebetween an optically transparent source support substrate (may be referred to herein as “donor substrate”) having coated on one side a thin film of material. However, prior coatings do not provide acceptable anti-reflectivity properties and/or deposition control for some applications. For example, simply using some combination of ceramics, copper, silver and gold may not be suitable for the manufacturing and/or repair of certain components.

### SUMMARY OF THE DISCLOSURE

According to one aspect of the disclosure, a donor composition used in a substrate repair process includes a donor substrate. The donor composition also includes a first layer of a first metallic material disposed adjacent to the donor substrate. The donor composition further includes a second layer of a second metallic material disposed adjacent to the first layer. The donor composition yet further includes a third layer of a third metallic material disposed adjacent to the second layer. The donor composition also includes a plurality of deposition layers of one or more metallic materials disposed adjacent to the third layer.

According to another aspect of the disclosure, an anti-reflective coating for a donor substrate comprising a plurality of layers is provided, wherein the maximum thickness of each of the plurality of layers is 20 nm.

These aspects and other advantages and features are apparent from the following description taken in conjunction with the drawings.

### BRIEF DESCRIPTION OF THE DRAWINGS

The embodiments set forth in the drawings are illustrative and exemplary in nature and not intended to limit the subject matter defined by the claims. The following detailed description of the illustrative embodiments can be understood when read in conjunction with the following drawings, where like structure is indicated with like reference numerals and in which:

FIG. 1 is a schematic, pictorial illustration of a system for direct writing on a substrate, in accordance with an embodiment of the disclosure;

FIG. 2 is a schematic side view showing additional details of the system of FIG. 1, in accordance with an embodiment of the disclosure;

FIG. 3A is a perspective view of an electronic component having an open defect;

FIG. 3B is a perspective view of the open defect repaired with the embodiments disclosed herein;

FIG. 4A is a perspective view of an electronic component having a short defect;

FIG. 4B is a perspective view of the short defect repaired with the embodiments disclosed herein;

FIG. 5 is a perspective, simplified view of the system and method of repairing (“open” defects”) a substrate disclosed herein; and

FIG. 6 is a schematic view of layers of a donor having a coating for use in the system and method of repairing a substrate.

### DETAILED DESCRIPTION

Embodiments disclosed herein relate to a coating for a donor substrate which enhances the capabilities and usability of Laser Induced Forward Transfer (LIFT). The enhancements offered by these embodiments are useful in PCB, IC Substrate, FPD manufacturing, printing of metal circuitry on various substrates (e.g., glass, paper, plastic, ceramic, etc.), and printed 3D metal structures. The disclosed techniques are not limited to these specific application contexts, however, and aspects of the embodiments described herein may also be applied to LIFT-based printing on acceptor substrates of other sorts, including printing of both metallic and non-metallic materials. Specifically, these techniques may be adapted for use in various printed electronics and three-dimensional (3D) printing applications.

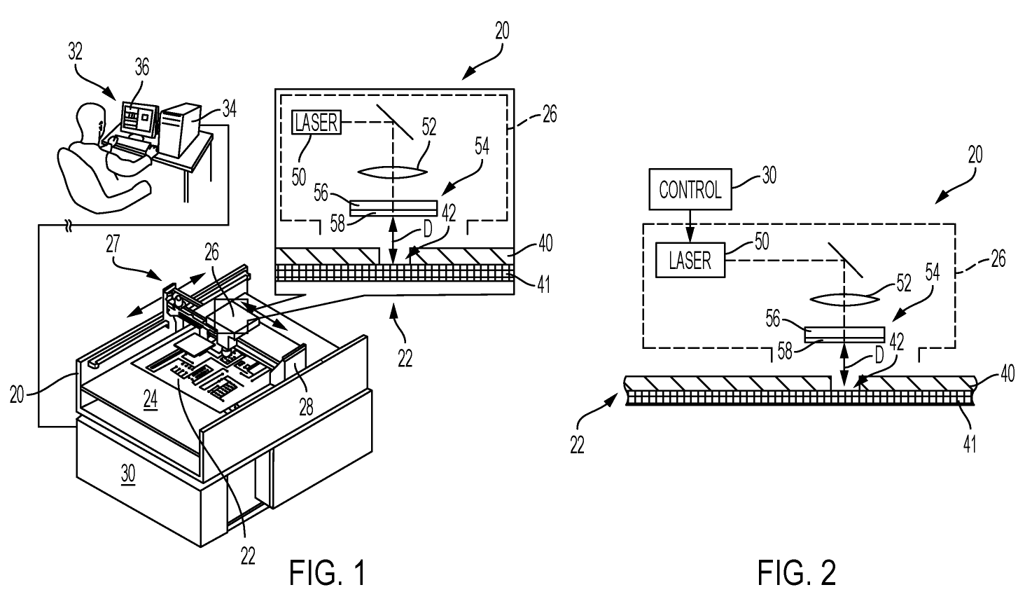

Referring now to FIG. 1, a schematic illustration of a system for direct writing on a substrate 41 is provided, in accordance with an embodiment of the disclosure. This system and its components are shown solely to illustrate an example environment in which the embodiments described herein may be implemented. Such techniques may similarly be carried out using suitable equipment of other types and in other configurations. As shown, material 40 is deposited on the substrate 41. The substrate 41 may be part of a printed circuit board (PCB), flat panel display or glass type substrate, or other material composition that may have a conductive material 40 deposited on, onto, into, or within the substrate 41. For example, the material 40 may be a conductive trace made of copper deposited into the substrate 41.

The system of FIG. 1 is built around a print and/or direct write apparatus 20, which operates on the substrate 41, which is held on a mounting surface 24 of the apparatus 20, to write, form, or print a pattern such as an electronic circuit on the substrate 41. This writing may define a Flat Panel Display (FPD) or a printed circuit board (PCB) 22. The terms “Flat Panel Display”, “FPD”, “printed circuit board” and “PCB” are used herein to refer generally to any sort of a dielectric, metal, or semiconductor substrate on which conductive traces are deposited, regardless of the type of substrate material and the process used for deposition. Apparatus 20 may be used to deposit new layers such as printing of metal circuitry on various substrates or in any other electronic devices.

Apparatus 20 comprises an optical assembly 26, containing a suitable laser and optics for LIFT and associated operations on the substrate, as shown in greater detail in FIG. 2. Alternatively, the laser may be contained in a separate unit, not shown in the figures, with a suitable optical connection to assembly 26. In some embodiments, direct printing or imaging applications, such as patterning or layer deposition on a PCB or FPD or any other pertinent device, may include other diagnostic capabilities that may be in-situ (i.e., monitoring during the printing process), integrated (i.e., monitoring selected devices immediately after completion of the LIFT process), or offline, by a stand-alone diagnostics system.

The optical assembly 26 is movably mounted to a positioning assembly 27 that includes a bridge 28 that extends across the mounting surface 24. The positioning assembly 27 is arranged to facilitate the positioning of the optical assembly 26 over pertinent sites – or sites of interest – on the substrate 41, by linear and/or vertical motion along the axes of apparatus 20. The positioning assembly 27 is arranged to enable the optical assembly 26 to move along the bridge 28, along a lateral axis of the apparatus 20 such that the optical assembly 26 may move across the surface of the substrate 41 and/or mounting surface 24, as shown by the lateral motion arrow in FIG. 1. The positioning assembly 27 is further arranged to enable the optical assembly 26 and the bridge 28 to move along a longitudinal axis of the apparatus 20 such that the optical assembly 26 may move along the surface of the substrate 41 and/or mounting surface 24, as shown by the longitudinal motion arrow in FIG. 1. In some embodiments, the positioning assembly 27 may be arranged to enable the optical assembly 26 to move vertically with respect to the mounting surface 24 and/or bridge 28. A control unit 30 controls the operation of the optical assembly 26 and positioning assembly 27, and carries out additional functions such as temperature control, so as to carry out the required inspection, printing, writing, patterning and/or other manufacturing and repair operations, as described below.

Typically, control unit 30 communicates with an operator terminal 32, comprising a general-purpose computer including a processor 34 and a display 36, along with a suitable user interface and software.

FIG. 2 is a schematic side view showing details of apparatus 20, and particularly of optical assembly 26, in accordance with an embodiment of the disclosure. The optical assembly 26 may be provided as part of an automated optical shaping system to repair defects in the material 40 that are disposed on the substrate 41. The optical assembly 26 may include a laser 50 that emits pulsed radiation, which is focused by suitable optics 52 to form a laser beam. The laser may comprise, for example, a pulsed laser with frequency-doubled output, which permits the pulse amplitude and duration to be controlled conveniently by control unit 30. Optics 52 are similarly controllable in order to adjust the location and size of the focal spot formed by the laser beam. In some embodiments it may thus be possible, with suitable adjustment of the laser and optical parameters, to use the same laser 50 for several or all of the pre-treatment, LIFT, and post-treatment steps. Alternatively, an additional laser (not shown), with different beam characteristics, may be used for some of these steps. It is possible that such an additional laser, if used, operate at the same wavelength as laser 50 in order to simplify the optical setup. In another embodiment the additional laser may operate in another wavelength and another optics setup, which may be dedicated for the described purpose, or for multiple purposes.

Optical assembly 26 is shown in FIG. 2 in the LIFT configuration. Optics 52 focus the beam from laser 50 onto a donor 54, which comprises a donor substrate 56 with a donor film 58. Typically, substrate 56 comprises a transparent optical material, such as glass or a plastic sheet, or other types of substrates such as silicon wafers, flexible plastic foils, ceramic or glass, and typical PCB substrates (e.g., epoxy based). The beam from laser 50 is aligned (by motion assembly 28) with the site of defect 42, and donor 54 is positioned above the site at a desired gap width D from a substrate 41 of PCB 22. The gap width may vary depending on the application. By way of non-limiting example, a gap width of at least 0.1 mm may be present, but gap widths of 0.2 mm or even 0.5 mm or greater can be used, subject to proper selection of the laser beam parameters.

In LIFT processes, PCB 22 is also known as receiver or acceptor. Optics 52 focus the laser beam through the outer surface of substrate 56 onto film 58, thereby causing droplets of molten metal to be ejected from the film, across the gap and onto the surface of device substrate.

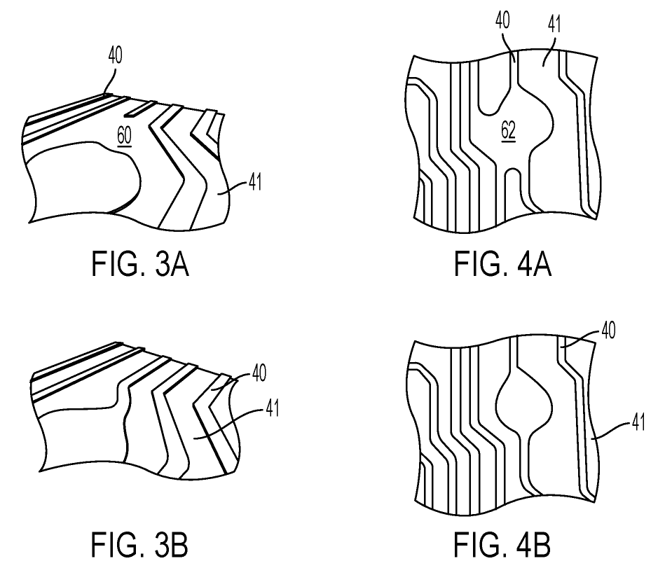

FIGS. 3A, 3B, 4A and 4B illustrate two examples of repairs which may be carried out with the embodiments disclosed herein. In particular, FIG. 3A illustrates an “open” circuit defect. As shown, an area on the substrate 41 where a conductive material such as copper is missing in the circuit or material 40. The area of missing copper or open is referenced generally with numeral 60. FIG. 3B illustrates a post-repair state where copper has been deposited on the substrate 41 to repair the open circuit. Conversely, FIG. 4A illustrates a “short” circuit defect. As shown, an area on the substrate 41 contains excessive copper for the circuit or material 40 such that circuit traces that should be spaced apart from each other on the substrate 41 are in contact with each other. The area of excessive copper is referenced generally with numeral 62. FIG. 4B illustrates a post-repair state where copper has been removed by ablation from the substrate 41 by the laser 50 to repair the short circuit.

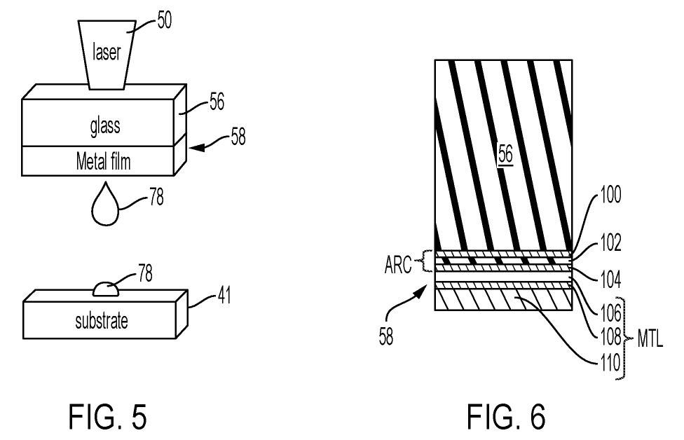

FIG. 5 is a schematic, sectional illustration of the system and method associated with the LIFT process disclosed herein, in accordance with an embodiment of the disclosure. In the illustrated embodiment, a beam from the laser 50 passes through the donor's substrate 56 and melts at least one layer of a metal film 58, disposed on a surface of the donor substrate 56, to form a liquid melt 78 of a mixture of layers of metal film 58. The liquid melt propagates towards the defect on the substrate 41 by a pressure vector, which is typically normal to the transparent substrate 56 and formed by melting and at least partially vaporizing of the metal film 58. The liquid melt 78 is in the form of a metal droplet. The liquid melt droplet departs from the donor 54 in a liquid state and travels towards the substrate 41or the acceptor. The droplet of liquid melt 78 lands on the surface of the substrate 41 and solidifies to generate a solid alloy. The droplet of liquid melt 78 may have a substantially similar material composition as the material 40 disposed on the substrate 41 that is being or to be repaired.

FIG. 6 is a schematic, sectional view showing details of multiple layers of the donor 54, in accordance with an embodiment of the disclosure. The donor 54 includes the substrate 56 which is formed of a material substantially transparent to the laser 50 applied in the LIFT process. The metal film 58 may be coated or otherwise deposited onto a surface of the substrate 56 opposite a surface of the substrate 56 that is arranged to face the laser 50. The metal film 58 may include several metallic layers that are melted by the laser 50 during the repair process.

The donor substrate 56 may be any suitable substantially transparent material, such as glass for example. In one non-limiting example, the donor substrate 56 is borosilicate glass substrate. The thickness of the layer of donor substrate 56 may vary depending upon the particular application. By way of non-limiting example, the donor substrate 56 may be about 1 mm thick.

Adjacent the donor substrate 56 is the metal film 58. The metal film 58 includes an anti-reflective layer or anti-reflective coating disposed between a surface of the donor substrate 56 and a material transfer coating or material transfer layer. The anti-reflective layer or anti-reflective coating is referred to as “ARC” in FIG. 6. The material transfer coating or material transfer layer is referred to as “MTL” in FIG. 6.

The anti-reflective coating enhances the control of the material deposition process by preventing the layer(s) of copper in the MTL from acting as a mirror that reflects the laser beam from the laser 50 away from the metal film 58 during application of the laser. The anti-reflective coating consists of metallic materials to minimize reflection of the laser beam by the MTL. In the illustrated embodiment, three layers are present in the ARC. By way of non-limiting example, a layer 100 immediately adjacent the donor substrate 56 includes titanium or may be a titanium alloy. The thickness of layer 100 ranges from about 1 nm to about 10 nm. In an embodiment, the thickness of layer 100 is about 5 nm. By way of non-limiting example, a layer 102 immediately adjacent layer 100 includes silicon. The thickness of layer 102 ranges from about 8 nm to about 20 nm. In an embodiment, the thickness of layer 102 is about 13 nm. By way of non-limiting example, a layer 104 immediately adjacent layer 102 includes titanium or may be a titanium alloy. The thickness of layer 104 ranges from about 1 nm to about 10 nm. In an embodiment, the thickness of layer 104 is about 6 nm.

The materials, thicknesses, and order of layers 100, 102, 104 of the anti-reflective coating specified above are used in conjunction with a wavelength of 532 nm of the laser 50. The materials, thicknesses, and order affect the final properties of the anti-reflective coating via efficiency of the laser absorption. The material selections are low in cost, have suitable adhesion properties, lead to high absorption by their combination and do not negatively interact with each other during operation. There is a range of absorption window of the anti-reflective coating which works well with the LIFT process described herein. Working at the maximum end of the absorption window leads to high efficiency droplet generation, relatively high droplet volumes and a large working window in terms of laser energy variations in the LIFT process.

The material and thickness specified above for each layer 100, 102, 104 of the anti-reflective coating may vary for laser wavelengths other than 532 nm. For example, possible suitable alternatives for the materials specified above in one or more of the layers 100, 102, 104 may be tungsten, zirconium, and hafnium, for example.

The ARC coating is disposed between the donor substrate 56 and the MTL. The MTL may include additional layers of metal that are melted by the laser 50 and deposited on the substrate 41. By way of non-limiting example, a layer 106 immediately adjacent layer 104 includes copper or may be a copper alloy. The thickness of layer 106 is about 100 nm +/- 5 nm in some embodiments. By way of non-limiting example, a layer 108 disposed between layers 106 and 110 may be any type of metal capable of producing a stable alloy with adjacent layers 106 and 110. The thickness of layer 108 is about 15 nm +/- 5 nm in some embodiments By way of non-limiting example, a layer 110 immediately adjacent layer 108 includes copper or may be a copper alloy. The thickness of layer 110 is about 400 nm +/- 20 nm in some embodiments. As with the ARC coating layers 100, 102, 104, the MTL coating layers 106, 108, 110 of the metal film 58 may be formed of materials and thicknesses which differ from those exactly specified above.

In at least one embodiment, the MTL may include at least one layer comprising a copper silver alloy or other alloy. The at least one layer may be disposed as a coating on the donor substrate 56 and replace layers 106, 108, 110.

In further embodiments, the MTL may be disposed directly on the donor substrate 56 and the ARC may not be provided. The efficiency of the heating of the MTL of the metal film 58 by the laser 50 may decrease and therefore the efficiency of the transfer of the liquid melt 78 from the metal film 58 to the defect in the material 40 on the substrate 41 may decrease.

The anti-reflective coating disclosed herein consists of thin metallic layers in contrast to prior donor coatings which are typically based on relatively thick ceramic materials For example, in some embodiments, the maximum thickness of any of the ARC layers 100, 102, 104 is about 20 nm. The embodiments of the coating disclosed herein improve the printing quality since the ratio between droplet volume to total volume results in less debris. Additionally, the coating and process disclosed herein may yield lower volume droplets to incorporate in smaller repair operations.

The terminology used herein is for the purpose of describing particular aspects only and is not intended to be limiting. As used herein, the singular forms “a,” “an,” and “the” are intended to include the plural forms, including “at least one,” unless the content clearly indicates otherwise. “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof. The term “or a combination thereof” means a combination including at least one of the foregoing elements.

It is noted that the terms “substantially ” and "about" may be utilized herein to represent the inherent degree of uncertainty that may be attributed to any quantitative comparison, value, measurement, or other representation. These terms are also utilized herein to represent the degree by which a quantitative representation may vary from a stated reference without resulting in a change in the basic function of the subject matter at issue.

While particular embodiments have been illustrated and described herein, it should be understood that various other changes and modifications may be made without departing from the spirit and scope of the claimed subject matter. Moreover, although various aspects of the claimed subject matter have been described herein, such aspects need not be utilized in combination. It is therefore intended that the appended claims cover all such changes and modifications that are within the scope of the claimed subject matter.

What is claimed is:

1. A donor composition used in a substrate repair process comprising:
a donor substrate;
a first layer of a first metallic material disposed adjacent to the donor substrate;
a second layer of a second metallic material disposed adjacent to the first layer;
a third layer of a third metallic material disposed adjacent to the second layer; and
a plurality of deposition layers of one or more metallic materials disposed adjacent to the third layer.

2. The donor composition of claim 1, wherein the plurality of deposition layers have a thickness greater than a thickness of each of the first layer, the second layer and the third layer.

3. The donor composition of claim 1, wherein the first layer is formed of titanium.

4. The donor composition of claim 1, wherein the second layer is formed of silicon.

5. The donor composition of claim 1, wherein the third layer is formed of titanium.

6. The donor composition of claim 1, wherein the first layer and the third layer are formed of the same metallic material.

7. The donor composition of claim 1, wherein at least one of the first layer, the second layer and the third layer is selected from the group of tungsten, zirconium and hafnium.

8. The donor composition of claim 1, wherein the first layer has a thickness ranging from 1 nm to 10 nm.

9. The donor composition of claim 1, wherein the second layer has a thickness ranging from 8 nm to 20 nm.

10. The donor composition of claim 1, wherein the third layer has a thickness ranging from 1 nm to 10 nm.

11. An anti-reflective coating for a donor substrate comprising a plurality of layers, wherein the maximum thickness of each of the plurality of layers is 20 nm.

12. The anti-reflective coating of claim 11, wherein the plurality of layers comprises:
a first layer of a first metallic material;
a second layer of a second metallic material disposed adjacent to the first layer; and
a third layer of a third metallic material disposed adjacent to the second layer.

13. The anti-reflective coating of claim 12, wherein the first layer is formed of titanium.

14. The anti-reflective coating of claim 12, wherein the second layer is formed of silicon.

15. The anti-reflective coating of claim 12, wherein the third layer is formed of titanium.

16. The anti-reflective coating of claim 12, wherein the first layer and the third layer are formed of the same metallic material.

17. The anti-reflective coating of claim 12, wherein at least one of the first layer, the second layer and the third layer is selected from the group of tungsten, zirconium and hafnium.

18. The anti-reflective coating of claim 1, wherein the first layer has a thickness ranging from 1 nm to 10 nm.

19. The anti-reflective coating of claim 1, wherein the second layer has a thickness ranging from 8 nm to 20 nm.

20. The anti-reflective coating of claim 1, wherein the third layer has a thickness ranging from 1 nm to 10 nm.
